(19) United States
(12) Patent Application Publication
(10) Pub. No.: US 2012/0052216 A1
(43) Pub. Date: Mar. 1, 2012

(54) GAS DISTRIBUTION SHOWERHEAD WITH HIGH EMISSIVITY SURFACE

(75) Inventors: Hiroji Hanawa, Sunnyvale, CA (US); Kyawwin Jason Maung, Daly City, CA (US); Hua Chung, San Jose, CA (US); Jie Cui, Albany, CA (US); David Bour, Cupertino, CA (US); Wei-Yung Hsu, San Jose, CA (US); Liang-Yuh Chen, Foster City, CA (US)

(73) Assignee: APPLIED MATERIALS, INC., Santa Clara, CA (US)

(21) Appl. No.: 13/154,060

(22) Filed: Jun. 6, 2011

Related U.S. Application Data
(60) Provisional application No. 61/377,850, filed on Aug. 27, 2010.

(51) Int. Cl. C23C 16/48

(52) U.S. Cl. 427/582; 118/722

(57) ABSTRACT

Embodiments of the present invention provide methods and apparatus for surface coatings applied to process chamber components utilized in chemical vapor deposition processes. In one embodiment, the apparatus provides a showerhead apparatus comprising a body, a plurality of conduits extending through the body, each of the plurality of conduits having an opening extending to a processing surface of the body, and a coating disposed on the processing surface, the coating being about 50 microns to about 200 microns thick and comprising a coefficient of emissivity of about 0.8, an average surface roughness of about 180 micro-inches to about 220 micro-inches, and a porosity of about 15% or less.

### CROSS-REFERENCE TO RELATED APPLICATIONS:

This application claims benefit of United States Provisional Patent Application Ser. No. 61/377,850 (Attorney Docket No. 015428L), filed Aug. 27, 2010, which is incorporated herein by reference.

### BACKGROUND OF THE INVENTION

1. Field of the Invention

Embodiments of the present invention generally relate to methods and apparatus for chemical vapor deposition (CVD) of materials onto a substrate, and, in particular, to surface treatments for process chamber components, including the structure and coating of showerheads and the forming of a surface coating with a high emissivity for use in thin film deposition chambers, such as those used for metal organic chemical vapor deposition (MOCVD) and/or hydride vapor phase epitaxy (HVPE).

2. Description of the Related Art

Chemical vapor deposition (CVD) chambers are typically utilized in the manufacture of semiconductor devices. CVD chambers may be adapted to perform one or more deposition processes on single substrates or wafers, or to perform one or more deposition processes on a batch of substrates or wafers. A gas distribution showerhead delivers precursors to a processing region adjacent to, commonly above, a substrate or substrates located in the chamber, to deposit materials, such as thin films, onto the substrate(s). Process temperature in thermal CVD deposition processes affects film formation rate and film properties. The entire surface of the substrate, or each substrate in a batch of substrates, must be exposed to the same, within reasonable tolerance, temperature to ensure deposition uniformity over the substrate surface. One factor which affects the temperature in the processing region is the emissivity of the chamber hardware.

The gas distribution showerhead, as well as other hardware components in proximity of the processing region, such as the chamber body, is generally fabricated from low emissivity materials. When the chamber hardware is in a new condition, i.e., non-oxidized or not corroded by process gas chemistries, the emissivity is known and is typically low or relatively reflective. However, the properties of the chamber surfaces may degrade over time, and the emissivity of the surfaces may change during repeated processing of substrates in the chamber, which may result in temperature variations across the substrate, from substrate to substrate where a plurality of substrates are processed simultaneously, and from process run-to-process run (Le., wafer to wafer or batch to batch). The emissivity of chamber component changes because the chamber component surfaces become covered with deposition materials and/or become corroded, i.e., oxidized or otherwise chemically modified. The substrate temperature between a process-run (i.e., from wafer to wafer or batch to batch) will tend to drift as the emissivity of the chamber components changes. Thus, the change in emissivity of the chamber components affects the temperature of the processing region, and thus the temperature of the substrates, which affects film formation and film properties on the substrates.

In one example, the substrate or substrates are supported in the processing region by a substrate support positioned between a heat source, such as lamps, and a gas distribution showerhead. The substrate support has, by virtue of its architecture, limited conductive heat transfer paths to other chamber components, in order to enhance temperature uniformity or the control of temperature uniformity of the substrate support. However, this same design makes direct heating of the substrate support, such as by resistance heating with an embedded resistance heater or with a support-embedded fluid circulation style heater problematic. As a result, the substrate support is indirectly heated from lamps arranged below or behind the substrate support, and heat impinges the side of the substrate support opposing the gas distribution showerhead. A portion of this indirect heat is absorbed by the substrate support and substrate(s) while another portion of this indirect heat is radiated toward a surface of the gas distribution showerhead, which is absorbed or radiated from the showerhead surface. The quantity of radiated heat is highly dependent upon the emissivity of the showerhead surface. Thus, the temperature of the processing region is a function of, indirectly, by the balance, or imbalance, of the heat input to the chamber by the lamps. The heat absorbed by the gas distribution showerhead and removed by active cooling of the gas distribution showerhead, and the heat emitted from the gas distribution showerhead, the last part of the balance being a function of the changing emissivity of the surface of the gas distribution showerhead. Regulation of the temperature in the processing region is facilitated primarily by active cooling of the gas distribution showerhead, in order to remove heat from the substrate(s) and the substrate support as well as other chamber components, and heat input by the lamps. When the heat reaching the substrate(s) is equal to that leaving the substrate(s), the substrate(s) maintain a desired temperature. If there is a difference in the two heat values, the temperature of the substrate(s), and the substrate support, changes.

As described above, the indirect heating of the substrate(s) and substrate support relies on radiative heating. This is dependent upon a number of factors, but one major contributor to the amount of heat reaching, or leaving the substrate(s), is the emissivity of the heat exchanging surface. Higher emissivity of the heat exchanging surface results in more heat absorption, and less heat radiation (reflection) from those surfaces. If the emissivity changes, the resultant heat balance to maintain a set or desired substrate temperature will change. In particular, in the system described, the substrate temperature is seen to drift as a result of an emissivity change of the gas distribution showerhead. Essentially, the gas distribution showerhead begins processing as a highly heat reflective element, and thus the energy from the lamps reaching the showerhead tends to be emitted therefrom, resulting in a higher substrate temperature. However, as processing occurs, the emissivity changes, and thus the heat balance of the system changes, resulting in undesirable lowering or change in substrate temperature. This can be ameliorated to some extent by increasing the heat energy from the lamps, decreasing the heat removed by the showerhead, or both, but the drift occurs to an extent that the chamber must be manually cleaned at an unacceptable frequency. Furthermore, it has been found that after cleaning, the chamber does not recover in the heat balancing properties the gas distribution showerhead had when new.

Numerous materials for chamber components are currently utilized and/or have been explored. However, all of the materials experience an emissivity change due to adhesion of precursor materials on the exposed surfaces, or corrosion or oxidation of these exposed surfaces. Further, although the materials may be cleaned, the emissivity of the surfaces may not be cleaned to the level of emissivity of a new surface and/or the cleaned surface will experience an emissivity change during subsequent processing. The emissivity changes result in process drift, which requires additional monitoring and tuning that must be altered based on the monitored process to provide repeatable wafer-to-wafer and within-wafer deposition results.

Therefore, there is a need for a gas distribution showerhead, and other chamber components, that enables stable emissivity characteristics in order to reduce temperature and/or process drift.

### SUMMARY OF THE INVENTION

The present invention generally provides improved methods for surface coatings applied to process chamber components utilized in chemical vapor deposition (CVD) processes and apparatus utilized in CVD processes having a surface coating according to embodiments described herein. In one embodiment, a showerhead apparatus is provided. The showerhead apparatus comprises a body, a plurality of conduits extending through the body, each of the plurality of conduits having an opening extending to a processing surface of the body, and a coating disposed on the processing surface, the coating being about 50 microns to about 200 microns thick and comprising a coefficient of emissivity of about 0.8, an average surface roughness of about 180 micro-inches to about 220 micro-inches, and a porosity of about 15% or less.

In another embodiment, a deposition chamber is provided. The deposition chamber comprises a chamber body having an interior volume contained between interior surfaces of the chamber body, interior surfaces of a gas distribution showerhead, and interior surfaces of a dome structure, a substrate support disposed in the interior volume in an opposing relationship to the gas distribution showerhead, and one or more lamp assemblies directing light through the dome structure. The gas distribution showerhead comprises a body, a plurality of conduits disposed in the body, each of the plurality of conduits having an opening extending to the interior surface of the body to deliver one or more gases to the interior volume, and a coating disposed on the interior surfaces of the gas distribution showerhead.

In another embodiment, a method for processing a substrate is provided. The method includes applying a coating to one or more surfaces of a body surrounding a processing volume in a chamber, transferring a first batch of one or more substrates to the processing volume of the chamber, providing an input energy to the processing volume of the chamber to heat the first batch of one or more substrates to a set-point temperature and perform a first deposition process on the one or more substrates, transferring the one or more substrates out of the processing volume, transferring a second batch of one or more substrates to the processing volume of the chamber, and heating the second batch of one or more substrates to the set-point temperature to perform a second deposition process on the one or more substrates, wherein the set-point temperature is maintained by varying the input energy by less than about 0.12%.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic plan view illustrating one embodiment of a processing system for fabricating semiconductor devices according to embodiments described herein.

FIG. 2 is a schematic cross-sectional view of a chemical vapor deposition (CVD) chamber for fabricating semiconductor devices according to one embodiment of the present invention.

FIG. 3 is an enlarged view of detail A shown in FIG. 2.

FIG. 4 is a partial, schematic, bottom view of the showerhead assembly from FIG. 2 and according to one embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present invention generally provide methods and apparatus for chamber components utilized in a chemical vapor deposition (CVD) process. In one embodiment, the method and apparatus may be utilized for deposition of Group III-nitride films using metal organic chemical vapor deposition (MOCVD) and/or hydride vapor phase epitaxy (HVPE) hardware. In one aspect, a processing chamber suitable for depositing materials to form a light emitting diode (LED), a laser diode (LD), or other device is provided.

Process temperature in thermal CVD deposition processes affects film formation rate and film properties. It has been found that with all process variables maintained equally, the process temperature between a process-run (i.e., from wafer to wafer or batch to batch) will tend to drift because the emissivity of the chamber components changes, and thus the temperature of the substrate or substrates will drift. The emissivity of the chamber component changes because the chamber component surfaces become covered with deposition materials and/or become corroded, i.e., oxidized or otherwise chemically modified. Although the parts in the chamber are periodically cleaned in an attempt to restore the surfaces to an original pre-process condition, the inventors have discovered that the surfaces do not recover to an original state after cleaning, or, the surfaces do not repeatedly recover to that state. As a result, the reflectance and emissivity of the component which is desired to be that of new component, is at a different state. Thus, the process temperature and temperature uniformity are different than that which is desired or expected even after cleaning.

The inventors herein have discovered that modifying the surface characteristics and/or coating the chamber components, in particular metal chamber components used in lamp heated CVD chambers, enables stabilization of the emissivity characteristics thereof over multiple processing and/or cleaning cycles. The term emissivity refers to the ratio of radiation emitted by a surface to the radiation emitted by a blackbody at the same temperature.

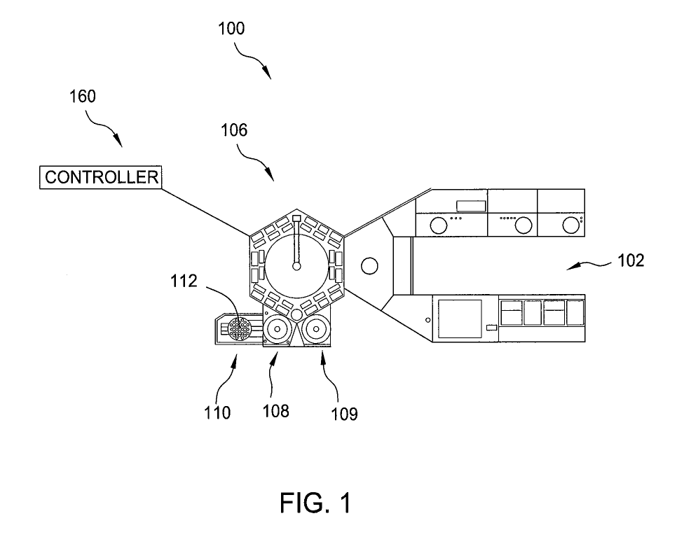

FIG. 1 is a schematic plan view illustrating one embodiment of a processing system 100 that comprises a plurality of process chambers 102 for depositing thin films onto a substrate utilizing a CVD process. In one embodiment, one or more of the plurality of process chambers 102 are CVD chambers that may be utilized in a CVD process, such as an MOCVD or HVPE process. The processing system 100 comprises a transfer chamber 106, at least one process chamber 102 coupled with the transfer chamber 106, a loadlock chamber 108 coupled with the transfer chamber 106, a batch loadlock chamber 109, for storing substrates, coupled with the transfer chamber 106, and a load station 110, for loading substrates, coupled with the loadlock chamber 108. The transfer chamber 106 comprises a robot assembly (not shown) operable to pick up and transfer substrates between the loadlock chamber 108, the batch loadlock chamber 109, and the process chamber 102. More than one process chamber 102 may also be coupled with the transfer chamber 106.

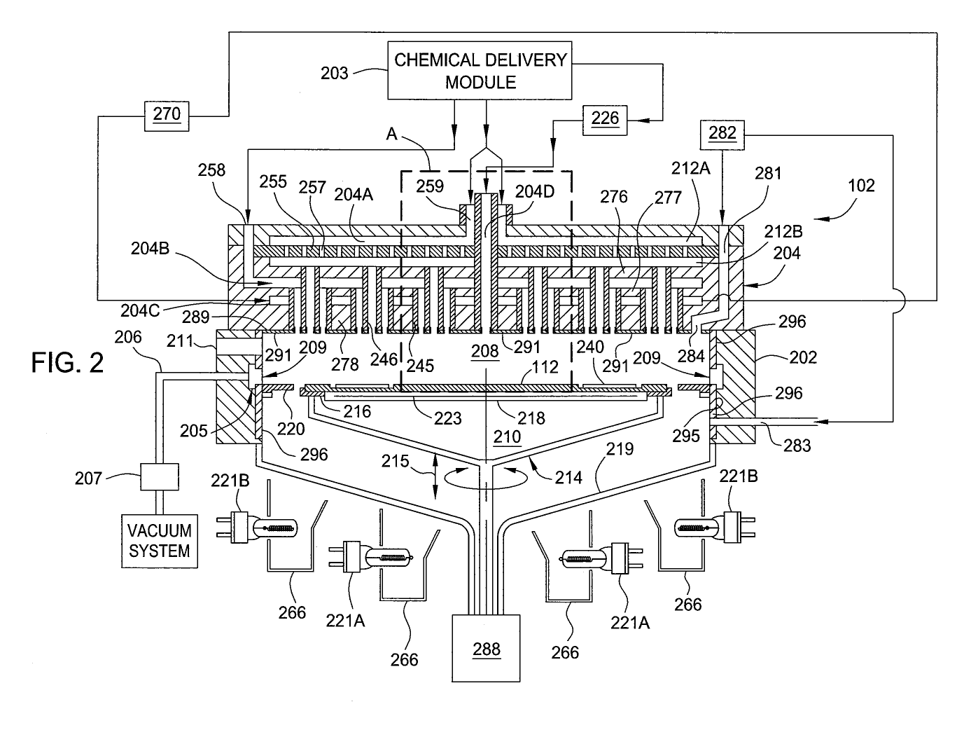

In the processing system 100, the robot assembly (not shown) transfers a substrate carrier plate 112 loaded with substrates through a slit valve (not shown) and into a single process chamber 102 to undergo chemical vapor deposition. In the embodiment described herein, the substrate carrier plate 112 is configured to receive a plurality of substrates in a spaced relationship as shown in FIG. 2. After some or all deposition steps have been completed, the substrate carrier plate 112 having the substrates thereon are transferred from the process chamber 102 via the robot assembly for further processing.

FIG. 2 is a schematic cross-sectional view of the process chamber 102 according to embodiments of the present invention. The process chamber 102 comprises a chamber body 202, a chemical delivery module 203 for delivering precursor gases, carrier gases, cleaning gases, and/or purge gases, a remote plasma system 226 with a plasma source, a substrate support structure 214 for supporting a substrate carrier plate 112, and a vacuum system. A sealable opening 211 is provided in the chamber body 202 for transfer of the substrate carrier plate 112 into and out of the process chamber 102. The chamber body 202 encloses a processing volume 208 that is bounded by a gas distribution showerhead 204, a portion of the chamber body 202 and the substrate carrier plate 112. In one embodiment, the surfaces of the gas distribution showerhead 204 and the portion of the chamber body 202 facing the processing volume 208 include coatings 291, 296, respectively, that shield the base material from deposition by-products.

The substrate support structure 214 may include a plurality of support arms having support pins that contact and support the substrate carrier plate 112 during processing. In some embodiments, an annular support ring 216 is utilized to support the substrate carrier plate 112. In other embodiments, the annular support ring 216 may be coupled to or used in conjunction with a plate 218 that contacts a backside of the substrate carrier plate 112 in a region between the annular support ring 216. The substrate support structure 214 is coupled to an actuator 288 providing vertical and/or rotational movement of the substrate support structure 214. The substrate support structure 214, the annular support ring 216, and the substrate carrier plate 112 may be fabricated from silicon carbide, graphite, quartz, alumina, aluminum nitride, and combinations thereof. In some embodiments, the plate 218 comprises a heating element 223 (e.g., a resistive heating element) for conductively heating and controlling the temperature of the substrate carrier plate 112 and substrates 240 positioned on the substrate carrier plate 112. One or more sensors (not shown), such as a thermocouple or a pyrometer, may be utilized to monitor temperature of the substrate carrier plate 112 and/or the temperature of the substrates 240. In embodiments where the annular support ring 216 is used, one or more pyrometers may be positioned to sense the temperature of the backside of the substrate carrier plate 112. In embodiments where the plate 218 is used, one or more thermocouples may be coupled to the substrate support structure 214 and/or the plate 218 to monitor the temperature of the substrate support structure 214, the temperature of the plate 218, and/or the temperature of the backside of the substrate carrier plate 112 during processing.

The gas distribution showerhead assembly 204 is configured as a double manifold showerhead (e.g., a first processing gas manifold 204A coupled with the chemical delivery module 203 via a first processing gas inlet 259 for delivering a first precursor or first process gas mixture to the processing volume 208, and a second processing gas manifold 204B for delivering a second precursor or second process gas mixture to the processing volume 208), which allows two different gas streams to be distributed by the showerhead without those gas streams mixing together within the showerhead. The first processing gas manifold 204A is bi-furcated into two sub-manifolds 212A and 212B by a blocker plate 255 (having a plurality of orifices 257) positioned across the first processing gas manifold 204A. The second processing gas manifold 204B coupled with the chemical delivery module 203 for delivering a second precursor or second process gas mixture to the processing volume 208 via a second processing gas inlet 258. In one embodiment, the chemical delivery module 203 is configured to deliver a suitable nitrogen containing processing gas, such as ammonia (NH₃) or other MOCVD or HVPE processing gas, to the second processing gas manifold 204B. The second processing gas manifold 204B is separated from the first processing gas manifold 204A by a first manifold wall 276 of the gas distribution showerhead assembly 204.

The chemical delivery module 203 delivers chemicals to the process chamber 102. Reactive gases (e.g., first and second precursor gases), carrier gases, purge gases, and cleaning gases may be supplied from the chemical delivery system through supply lines and into the process chamber 102. In one embodiment, the gases are supplied through supply lines and into a gas mixing box where they are mixed together and delivered to the gas distribution showerhead assembly 204. In one embodiment, the chemical delivery module 203 is configured to deliver a metal organic precursor to the first processing gas manifold 204A and the second processing gas manifold 204B. In one example, the metal organic precursor comprises a suitable gallium (Ga) precursor (e.g., trimethyl gallium (TMG), triethyl gallium (TEG)), a suitable aluminum precursor (e.g., trimethyl aluminum (TMA)), or a suitable indium precursor (e.g., trimethyl indium (TMIn)). A purge gas (e.g., a nitrogen containing gas) from a purge gas source 282 may be distributed through a plurality of orifices 284 into the process chamber 102 from the gas distribution showerhead assembly 204 through one or more purge gas plenums 281 (only one is shown). Alternatively or additionally, the purge gas may be delivered by to the process chamber 102 by a purge gas tube 283 (only one is shown).

The gas distribution showerhead assembly 204 further comprises a temperature control system for flowing a thermal control fluid through the gas distribution showerhead assembly 204 to help regulate the temperature of the gas distribution showerhead assembly 204 (e.g., a temperature control channel 204C coupled with a heat exchange system 270). The second processing gas manifold 204B is separated from the temperature control channel 204C by a second manifold wall 277 of the gas distribution showerhead assembly 204. The temperature control channel 204C may be separated from the processing volume 208 by a third manifold wall 278 of the gas distribution showerhead assembly 204.

The process chamber 102 comprises a lower dome 219 made of a transparent material containing a lower volume 210 of the processing volume 208. Thus, the processing volume 208 is contained between the gas distribution showerhead assembly 204 and the lower dome 219. An exhaust ring 220 is utilized to direct exhaust gases from the process chamber 102 to exhaust ports 209 coupled to an exhaust channel, a vacuum pump 207 and a vacuum system. Radiant heat to the processing volume 208 may be provided by a plurality of lamps (e.g., inner lamps 221A and outer lamps 221B having reflectors 266).

The temperature of the walls of the process chamber 102 and surrounding structures, such as the exhaust passageway, may be further controlled by circulating a thermal control liquid through channels (not shown) in the walls of the process chamber 102. The thermal control liquid can be used to heat or cool the chamber body 202 depending on the desired effect. For example, hot liquid may help maintain an even thermal gradient during a thermal deposition process, whereas a cool liquid may be used to remove heat from the system during an in-situ plasma process for dissociation of a cleaning gas, or to limit formation of deposition products on the walls of the chamber. The heating provided by the lamps 221A, 221B, as well as the heating or cooling provided by the thermal control fluid from the heat exchange system 270 through the gas distribution showerhead assembly 204 and/or the heating or cooling by delivering thermal control liquid to the walls of the chamber body 202 maintains a processing temperature in the processing volume 208 of about 500° C. to about 1300° C., more specifically, about 700° C. to about 1300° C. In one embodiment, the input power to the lamps 221A and 221B is about 45 kW to about 90 kW to produce a processing temperature between about 900° C. and about 1,050° C., or greater, in the processing volume 208 of the process chamber 102. In one embodiment, the processing temperature is monitored by utilizing sensors, such as one or more thermocouples, that measure the temperature of the backside of the substrate carrier plate 112 (FIG. 1).

The third manifold wall 278 of the gas distribution showerhead assembly 204 includes a surface 289 facing the substrate support structure 214. The temperature of the surface 289, as well as other portions of the gas distribution showerhead assembly 204, are monitored and controlled during processing. The gas distribution showerhead assembly 204 is fabricated from stainless steel and the surface 289 is bare stainless steel having a coefficient of emissivity of about 0.17. In one embodiment, the surface 289 of the gas distribution showerhead assembly 204 facing the substrate support structure 214 includes a roughened surface to increase the emissivity of the surface 289 to greater than 0.17. The surface 289 may be roughened by bead blasting to increase the initial emissivity thereby limiting the change in emissivity caused by processing in the process chamber 102. Thus, roughening of the surface 289 lowers reflectivity and stabilizes thermal absorption of the base material of the gas distribution showerhead assembly 204.

In one embodiment, the surface 289 is bead blasted to provide a roughened surface having an average surface roughness (Ra) of about 80 micro inch (μ-inch) to about 120 μ-inch. The roughening of the surface 289 increases the initial emissivity of the surface 289, as compared to non-roughened surfaces, and reduces the emissivity change caused by corrosion or oxidation, which reduces process drift. In one embodiment, a #80 grit size is utilized to provide the roughened surface. The bead blasting may be applied at a pressure known to create the desired Ra using a desired grit size. In one aspect, the beads are allowed to enter any openings in the surface 289. In one aspect, the diameters of any openings in the gas distribution showerhead assembly 204 are greater than the grit size, and in particular, greater than the dimension of #80 grit size. The openings may be cleaned by coupling the gas distribution showerhead assembly 204 to a vacuum pump or disposing the gas distribution showerhead assembly 204 in a vacuum environment to remove and exhaust any grit that may have entered the openings in the gas distribution showerhead assembly 204. In another aspect, a purge gas may be delivered through the openings in the gas distribution showerhead assembly 204 at a pressure of about 80 psi to prevent or minimize any beads or grit from entering the openings.

In another embodiment, the surface 289 of the gas distribution showerhead assembly 204 facing the substrate support structure 214 includes a coating 291. Additionally, other surfaces of the process chamber 102 in proximity to the processing volume 208, such as interior surfaces 295 of the chamber body 202, may include a coating 296. In one embodiment, the gas distribution showerhead assembly 204 and the chamber body 202 comprise an electrically conductive material, such as a stainless steel material, for example 316L stainless steel. The coatings 291, 296 comprise a material that is compatible with process chemistry used in deposition and cleaning processes and are compatible with the extreme temperature applications utilized in MOCVD and HVPE processes. The coatings 291, 296 establish an emissivity of the chamber components to negate or stabilize emissivity fluctuations of the surfaces 289 and/or 295 and the base material thereof, in order to stabilize thermal absorption of the base material to faciltate repeated processing. In one embodiment, the coatings 291, 296 comprise a coefficient of emissivity of about 0.8 to about 0.85.

The coatings 291, 296 may comprise a ceramic material that is deposited on the surfaces 289, 295. It has been found that, when such coatings are applied to a metal surface, such as stainless steel, the emissivity of the surface of the components, after deposition and cleaning processes, is significantly closer to the emissivity of the clean, unused component surface. In one aspect, the coating 291 includes alumina or aluminum oxide (Al₂O₃), zirconium oxide (ZrO₂), yttrium (Y), yttrium oxide (Y₂O₃), chromium oxide (Cr₂O₃), silicon carbide (SiC), combinations thereof or derivatives thereof. The coatings 291, 296 may be deposited on the respective surfaces utilizing a thermal spraying method, such as plasma spraying. The coatings 291, 296 formed on the surfaces 289, 295 may have a thickness between about 50 microns (μm) to about 200 μm. The coatings 291, 296 may be porous. In one embodiment, the coatings 291, 296 include a porosity of less than about 10%, such as about 0.5% to about 10%, for example, about 8% to about 10% utilizing an optical method. In another embodiment, the coatings 291, 296 include a porosity of less than 15%, such as about 0.5% to about 15%, for example, between about 10% to about 15%, utilizing the Archimedes method. The coatings 291, 296 may be hydrophilic or wettable and include a contact angle of less than about 90 degrees, such as between about 0 degrees and 90 degrees. The coatings 291, 296 may be a white color after plasma spraying and remain substantially white in color even after several deposition and/or cleaning cycles. Further, the emissivity is substantially stable between the first use and a cleaning process. For example, the emissivity may be about 0.8 at the first use and about 0.81 prior to in-situ cleaning. Thus, the emissivity delta of the coatings 291, 296, as compared to a new, clean surface or a used, cleaned surface, is between about 0.8 to about 0.85. The emissivity delta provided by the coatings 291, 296 provides negligible compensation in power applied to the lamps 221A, 221B, which, in one embodiment, is less than about 100 Watts at a power set-point of about 80,000 Watts to about 90,000 Watts, which is used to provide a temperature of about 1,000° C. in the processing volume 208 and/or a substrate temperature of about 1,000° C. Although there may be a mismatch in coefficient of thermal expansion between the material of the gas distribution showerhead assembly 204 and the coatings 291, 296, the porosity of the coatings 291, 296 reduces stress in the coatings 291, 296. Thus, by providing the coatings 291, 296 with a porosity value as described above, the coatings 291, 296 are more elastic, which prevents cracking of the coatings 291, 296 during heating and cooling of the process chamber 102, particularly when the process chamber 102 is heated from room temperature at start-up or cooled to room temperature for service.

The plasma spray process is performed ex-situ at atmospheric pressure to form the coatings 291, 296. The plasma spray process includes preparation of the surfaces 289, 295 to increase adhesion of the coatings 291 and 296. In one embodiment, the surfaces 289, 295 are bead blasted to create a roughened surface to promote adhesion of the coatings 291, 296. In one aspect, the beads are #80 grit size aluminum oxide particles utilized to form a roughened surface with an Ra of about 80 micro inch (μ-inch) to about 120 μ-inch. A purge gas may be delivered through the gas distribution showerhead assembly 204 during bead blasting to prevent any particles from entering any openings formed on the surface 289. In one embodiment, a plasma spray consisting of a ceramic powder may be deposited on the surfaces 289, 295 after roughening. In one embodiment, the ceramic powder is 99.5% pure. In another embodiment, the ceramic powder is aluminum oxide (Al₂O₃). The plasma spray may be applied at a pressure to create the desired Ra using a desired powder size. In one aspect, a plasma of the ceramic powder is applied to the surfaces 289, 295 and any openings in the surfaces 289, 295 are covered or filled to prevent clogging. In another aspect, the plasma of the ceramic powder is allowed to at least partially enter any openings in the surfaces 289, 295. In one embodiment, a purge gas is delivered through the gas distribution showerhead assembly 204 during plasma spraying at a pressure of about 80 psi that prevents spray from entering any openings formed on the surface 289. In one aspect, the plasma spray is applied to the surface 289 such that any openings in the surface 289 are lengthened by an amount equal to the thickness of the coating 291 on the surface 289. In another embodiment, the purge gas is delivered through the gas distribution showerhead assembly 204 at a pressure less than about 80 psi that allows a portion of the spray to enter openings formed on the surface 289. In yet another embodiment, the plasma spray is allowed to cover the openings. In this embodiment, the openings may be re-machined to be reopened and sized after application of the coating, if desired.

The coatings 291, 296 may also be removed, if desired, so that the base material of the surfaces 289 and 295 may be refurbished. The coatings 291, 296 may be removed by bead blasting or utilizing chemicals to attack the interface between the surfaces 289 and 295 and break the bond between the coating and the base material. After the surfaces 289, 295 are cleaned, the coatings 291, 296 may be reapplied to the cleaned surfaces 289 and 295 according to the coating process described above and re-installed into the process chamber 102.

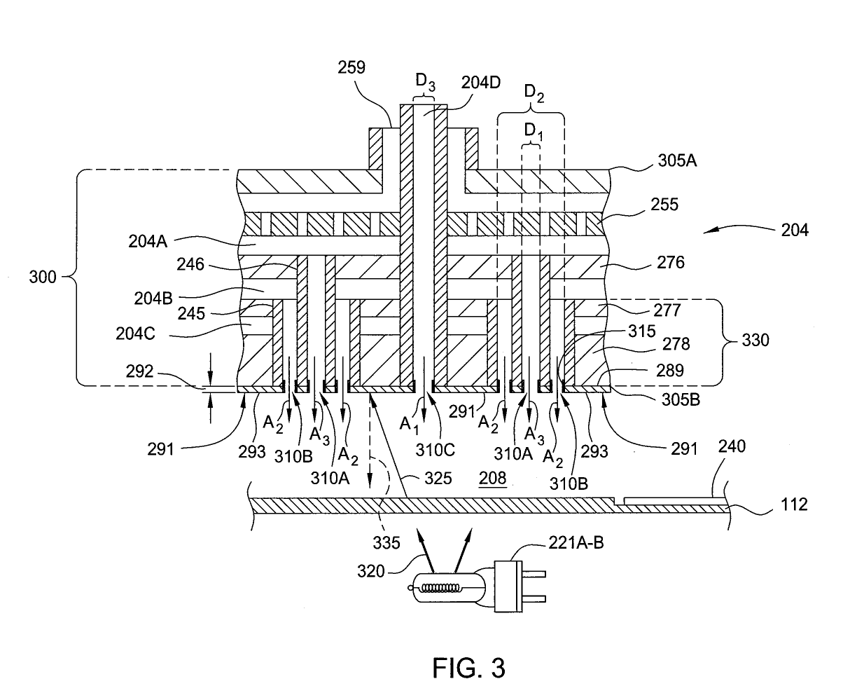

FIG. 3 is an enlarged view of detail A shown in FIG. 2, further showing a distribution of the coating 291 on the gas distribution showerhead assembly 204. The gas distribution showerhead assembly 204 comprises a body 300 having a first major side 305A and a second major side 305B. Referring to FIGS. 2 and 3, in one embodiment, the first precursor or first processing gas mixture, such as a metal organic precursor, is delivered from the first processing gas manifold 204A through the second processing gas manifold 204B and the temperature control channel 204C into the processing volume 208 by a plurality of inner gas conduits 246. The inner gas conduits 246 may be cylindrical tubes made of stainless steel located within aligned holes disposed through the first manifold wall 276, the second manifold wall 277, and the third manifold wall 278 of the gas distribution showerhead assembly 204. Each of the inner gas conduits 246 include an opening 310A in the second major side 305B. Each opening 310A is formed through the surface 289 to deliver the first precursor along a flow path A₃ to the processing volume 208. In one embodiment, the inner gas conduits 246 are each attached to the first manifold wall 276 of the gas distribution showerhead assembly 204 by suitable means, such as brazing.

In one embodiment, the second precursor or second processing gas mixture, such as a nitrogen precursor, is delivered from the second processing gas manifold 204B through the temperature control channel 204C and into the processing volume 208 through a plurality of outer gas conduits 245. The outer gas conduits 245 may be cylindrical tubes made of stainless steel. Each of the outer gas conduits 245 may be located concentrically about a respective inner gas conduit 246. Each of the outer gas conduits 245 include an opening 310B in the second major side 305B. Each opening 310B is formed through the surface 289 to deliver the second precursor along a flow path A₂ to the processing volume 208. The outer gas conduits 245 are located within the aligned holes disposed through the second manifold wall 277 and the third manifold wall 278 of the gas distribution showerhead assembly 204. In one embodiment, the outer gas conduits 245 are each attached to the second manifold wall 277 of the gas distribution showerhead assembly 204 by suitable means, such as brazing. Plasma species produced in the remote plasma system 226 from precursors delivered by an input line are flowed through a conduit 204D. Plasma species are dispersed through the gas distribution showerhead assembly 204 in a flow path A₁ to the processing volume 208. The plasma species flow through an opening 310C formed through the surface 289 of the gas distribution showerhead assembly 204.

In one embodiment, each of the openings 310A-310C include a diameter, such as an inside diameter D₁-D₃ and the coating 291 is applied to the surface 289 in a manner that lengthens the openings 310A-310C without a reduction in the diameters D₁-D₃. In one embodiment, the inside diameters D₁-D₃ are about 0.6 mm. In one aspect, the openings 310A-310C are lengthened in an amount equal to the thickness of the coating 291 without any reduction in the diameters D₁-D₃. In another embodiment, the coating 291 is allowed to at least partially cover a portion of the openings 310A-310C and enter the inside diameters D₁-D₃, shown as interior coating 315 In this embodiment, the openings 310A-310C are not covered or filled prior to plasma spraying. Thus, the coating 291 is allowed to reduce the size of the openings 310A-310C. In one embodiment, the thickness 292 of the coating is about 50 μm to about 200 μm on the surface 289 and the inside diameters D₁-D₃. In one aspect, the thickness 292 is chosen to correspond with the amount of open area percentage of each opening 310A-310C. In one example, the thickness 292 of the coating 291 is chosen to cover a portion of each opening 310A-310C leaving at least about greater than 80% of the opening diameter D₁-D₃. In one embodiment, the coating 291 is allowed to enter the openings 310A-310C to a depth of about 50 μm to about 200 μm from the surface 289. The opening 284 (FIG. 2) is not shown and may be at least partially covered by the coating 291 as described above in reference to openings 310A-310C.

In one embodiment, primary heat 320 from the lamps 221A and 221B is absorbed by the substrate carrier plate 112 and substrates 240. Secondary heat 325 from the substrate carrier plate 112 and substrates 240 is radiated into the processing volume 208. A portion of the secondary heat 325 is absorbed by a lower body 330 of the gas distribution showerhead assembly 204 where the coating 291 significantly lowers the reflectance of the surface 289. A majority of the secondary heat 325 is absorbed by a surface 293 of the coating 291, which serves to insulate the gas distribution showerhead assembly 204 from the secondary heat 325. The coating 291 does not degrade or discolor significantly during processing, which provides a substantially uniform emission of radiated energy 335 from the lower body 330 of the gas distribution showerhead assembly 204 into the processing volume 208. While not shown, secondary or radiant heat 325 from the substrate carrier plate 112 and substrates 240 is absorbed by the chamber body 202 (FIG. 2) and radiated energy 335 from the chamber body 202 into the processing volume 208 is substantially uniform, which is facilitated by the coating 291 on the interior surfaces 295 of the chamber body 202.

In some embodiments, the coating 291 may be applied to interior surfaces of the gas distribution showerhead assembly 204 that are exposed to precursor gases in order to prevent or reduce precursor adsorption on these surfaces. For example, in reference to FIG. 2, some or all surfaces in the conductance path of precursors, such as the interior surfaces of the conduit 204D, the first processing gas inlet 259, the second processing gas inlet 258, the first processing gas manifold 204A, second processing gas manifold 204B, the blocker plate 255 and orifices 257, as well as the interior surfaces of the inner gas conduits 246, may have the coating 291 applied thereto. The coating 291 prevents or significantly reduces precursor adsorption or sticking on the interior surfaces of the gas distribution showerhead assembly 204, which may result in non-uniform processing and film growth. For example, precursors such as trimethyl indium (TMIn) and bis (cyclopentadienyl) magnesium (Cp₂Mg) tend to easily adhere to metallic chamber surfaces. Thus, in a processing run, a portion of the precursor materials may adhere to the interior surfaces of the gas distribution showerhead assembly 204 and not reach the substrates 240, which may result in non-uniform deposition and/or non-uniform film growth resulting from the inefficient delivery of the precursor to the substrate. In multiple processing runs, the precursors adsorbed on the interior surfaces of the gas distribution showerhead assembly 204 may produce a “memory effect” where the adsorbed precursor materials are unintentionally detached from the surfaces and/or are carried by other precursor gases to the substrates 240 at unintended time intervals. The unintentional detachment of the precursors may detrimentally affect film quality by introducing the detached precursors to the substrates 240 outside of desired time intervals, by introducing the detached precursors as additional or excess reactive gases, and/or by introducing the detached precursors as particles in the film. Embodiments of the coating 291 applied to interior surfaces of the gas distribution showerhead assembly 204 that are exposed to precursor gases prevent or reduce the memory effect by minimizing adherence of the precursor to the metal surface. Thus, reduction of precursor adsorption on surfaces of the gas distribution showerhead assembly 204 maintains efficient gas delivery, and provides greater flow control and sharper on/off transitions, which results in improved film quality, desirable multi-quantum well formation, and improved sharpness in doped regions at junctions.

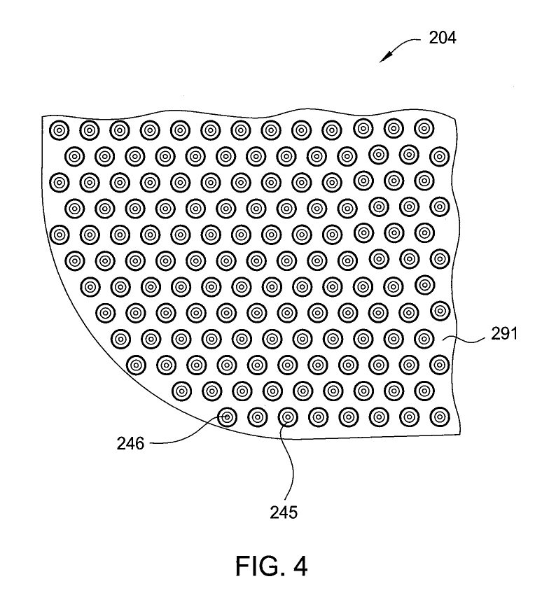

FIG. 4 is a partial, schematic, bottom view of the showerhead assembly 204 from FIG. 2 and according to one embodiment of the present invention. As depicted, the concentric tube configuration comprising the outer gas conduit 245 that delivers a second gas from the second processing gas manifold 204B and the inner gas conduit 246 that delivers a first gas from the first processing gas manifold 204A are arranged in a much closer and more uniform pattern. In one embodiment, the concentric tubes are configured in a hexagonal close packed arrangement. As a result, each of the first and second processing gases, delivered from the first processing gas manifold 204A and the second processing gas manifold 204B, is delivered more evenly across the substrates 240 positioned in the processing volume 208, resulting in significantly more deposition uniformity.

In summary, embodiments of the present invention include a gas distribution showerhead assembly 204 having concentric tube assemblies for separately delivering processing gases into a processing volume 208 of a process chamber 102. The gas distribution showerhead assembly 204, as well as other portions of the process chamber 102, may include a high emissivity coating 291, 296 disposed thereon to reduce emissivity variations of the components in proximity to the processing volume 208. The coatings 291, 296 provide a lower emissivity delta, or within-processing or run-to-run emissivity change, as compared to new component surfaces and/or cleaned component surfaces, which facilitates stable radiation of heat in the processing volume 208. Thus, power set points to heat the processing volume 208 are more stable according to embodiments described herein. This improves wafer-to-wafer repeatability without the need to adjust process parameters and/or perform frequent cleaning of the chamber components.

It has been found that by use of the coating 291, the heat applied to and removed from the processing volume 208 of an LED processing chamber, such as the process chamber 102, can be maintained more readily as compared to more conventional process chamber designs. The coated chamber components, which result in reduced emissivity variations, which generally lead to an improvement in wafer-to-wafer and within-wafer temperature uniformity results, and thus leads to an improved LED device performance repeatability. By use of the gas distribution showerhead assembly 204 as described herein, it has been found that the input energy, such as thermal energy provided to the substrates by the substrate heating source(s) to maintain the desired substrate processing temperature, for example conductive heating from a heating element 223 or radiant heat from the lamps 221A, 221B, remains in a relatively small range, such as a change in power applied to the heating source(s) of about less than about 0.5%, for example, between about 0.5% to less than about 0.2%, such as less than about 0.12% to maintain a desired set-point temperature. For instance, to maintain a set-point temperature of about 1,000° C., the power applied to the substrate heating source(s), such as the lamps 221A, 221B, varies by less than 100 Watts. In one example, to maintain a temperature set-point of about 1,000° C., with heat removal with fluid through the heat exchange system 270 maintained constant, the thermal energy provided to the substrates by the substrate heating source(s) varies by less than 100 Watts, which is used to achieve a substrate processing temperature. In another example, to maintain a power set-point of about 80,000 Watts, the thermal energy provided to the substrates by the substrate heating source(s) varies by less than 100 Watts, which is used to achieve a substrate processing temperature of about 1,000° C. Changes in power applied to the lamps 221A, 221B, and/or changes in the temperature or flow rate of thermal control fluid to compensate for emissivity drift is greatly reduced, according to embodiments described herein.

In one embodiment, the substrate carrier plate 112 (FIG. 1) utilized during processing comprises a surface area of about 95,000 mm² to about 103,000 mm², such as about 100,000 mm², and the input power to the lamps 221A and 221B may be varied based on this area to achieve a set-point processing temperature. In one embodiment, an input power to the lamps 221A and 221B is about 45 kW to achieve a processing temperature of about 900° C. measured at the backside of the substrate carrier plate 112. In another embodiment, an input power to the lamps 221A and 221B is about 90 kW to achieve a processing temperature of about 1,050° C. measured at the backside of the substrate carrier plate 112. Thus, a power density of input power to the lamps 221A and 221B may be about 0.45 W/mm² to about 0.9 W/mm² based on the surface area of the substrate carrier plate 112.

In another embodiment, the gas distribution showerhead assembly 204 utilized during processing comprises a surface area (i.e., area of the surface 289) of about 100,000 mm² to about 250,000 mm², such as about 200,000 mm², and the input power to the lamps 221A and 221B may be varied based on this area to achieve a set-point processing temperature. In one embodiment, an input power to the lamps 221A and 221B is about 45 kW to achieve a processing temperature of about 900° C. measured at the backside of the substrate carrier plate 112. In another embodiment, an input power to the lamps 221A and 221B is about 90 kW to achieve a processing temperature of about 1,050° C. measured at the backside of the substrate carrier plate 112. Thus, a power density of input power to the lamps 221A and 221B may be about 0.225 W/mm² to about 0.45 W/mm² based on the surface area of the gas distribution showerhead assembly 204.

In one example, data from sixteen deposition process cycles was acquired and the power delivered to the lamps 221A, 221B over the sixteen deposition and cleaning cycles remained substantially stable. In this example, a gas distribution showerhead assembly 204 having the coating 291 thereon experienced a 100 Watt drift at a lamp output power of about 80,000 Watts, as compared to an 8,000 Watt drift in lamp power at the same lamp output power for an uncoated gas distribution showerhead assembly. Thus, over the sixteen deposition process cycles, the gas distribution showerhead assembly 204 having the coating 291 thereon provided an 80× improvement in thermal control of the processing environment in which the substrates are placed. In this example, the temperature of the thermal control fluid delivered through the heat exchange system 270 and the temperature control channel 204C was monitored during deposition and cleaning processes to determine the variation in heat taken out of the gas distribution showerhead assembly 204. The energy removed from the gas distribution showerhead assembly 204 through the coating 291 was about 15.3 kW during deposition. It has been found, and one skilled in the art will appreciate, that the LED device yield will significantly vary if the substrate(s) processing temperature drifts more than a few degrees (e.g., +/−2.5° C.) from process-run to process-run. The LED device yield issue arises, at least in part, due to the variability in film thickness and light output created in the formed LED devices from process-run to process-run. Therefore, embodiments described herein prevent or minimize run-to-run substrate processing temperature variation or drift within an acceptable range (i.e., less than +/−2.5 ° C.) to repeatably produce an LED device having substantially the same film thickness and light output. It has been found that by use of the coating 291 described herein, the run-to-run average substrate processing temperature range is less than about +/−2° C. at a desired set-point processing temperature between 800° C. and 1,300° C., such as about 1,000° C. Thus, the utilization of the coating 291 as described herein minimizes process-run to process-run film thickness variations and within-wafer film thickness variations to produce an LED device with substantially the same light output characteristics.

Testing of a gas distribution showerhead assembly 204 having a coating 291 thereon showed a increase between cleaning intervals and an increase in the number of process-runs before film thickness drifted out of specification. For example, a gas distribution showerhead assembly 204 having a coating 291 thereon was utilized for 80 process-runs while maintaining film thickness per specification. This is compared to a gas distribution showerhead without a coating, where film thickness drifted out of specification after 10 process-runs. Therefore, in one aspect, the gas distribution showerhead assembly 204 having a coating 291 thereon as described herein increased the number of process-runs to about 80 before in-situ cleaning as compared to about 10 utilizing a showerhead without a coating. In some deposition processes, it has been found that the number of process-runs can be increased to about 300 before in-situ cleaning is needed. Thus, the gas distribution showerhead assembly 204 as described herein increases throughput by minimizing downtime of the chamber. Testing of a gas distribution showerhead assembly 204 having a coating 291 thereon also showed a temperature decrease in surfaces adjacent the processing volume 208, such as a temperature decrease in the surface of the substrate support structure 214 of about 40° C. It is believed that the decrease in the temperature of the substrate support structure was due to the higher emissivity of the surface of the coating 291, and thus the coating 291 improved radiant heat transfer to the gas distribution showerhead assembly 204 from the substrate support structure 214 and substrates. Thus, heat loss to the substrate support structure 214 results in a decreased temperature for the gas distribution showerhead assembly 204 utilizing the same power input to the lamps 221A, 221B.

Additionally, the coating 291 disposed on the gas distribution showerhead assembly 204 tends to insulate the body 300 from the heat delivered from the lamps 221A, 221B. As noted above, due to the increased emissivity of the coating 291, the gas distribution showerhead assembly 204 will absorb more thermal energy than an uncoated showerhead assembly. Therefore, due to high emissivity and insulating properties of the coating 291, the surface 293 of the coating 291 adjacent to the processing volume 208 will have a greater surface temperature than an uncoated metal showerhead, which can make the in-situ cleaning process performed between process runs more efficient and effective as compared to an uncoated showerhead performing the same process.

While the foregoing is directed to embodiments of the present invention, other and further embodiments of the invention may be devised without departing from the basic scope thereof, and the scope thereof is determined by the claims that follow.

1. A showerhead, comprising:
a body;
a plurality of conduits extending through the body, each of the plurality of conduits having an opening extending to a processing surface of the body; and
a coating disposed on the processing surface, the coating being about 50 microns to about 200 microns thick and comprising:
a coefficient of emissivity of at least about 0.8;
an average surface roughness of about 180 micro-inches to about 220 micro-inches; and
a porosity of about 15% or less.

2. The showerhead of claim 1, wherein the coating is white in color.

3. The showerhead of claim 1, wherein the coating is hydrophilic.

4. The showerhead of claim 3, wherein the coating includes a contact angle between about 0 degrees and about 90 degrees.

5. The showerhead of claim 1, wherein the body comprises a metallic material having an average surface roughness of about 80 micro inches to about 120 micro inches.

6. The showerhead of claim 5, wherein the metallic material comprises stainless steel.

7. The showerhead of claim 1, wherein the processing surface comprises an average surface roughness of about 80 micro-inches to about 120 micro-inches.

8. A deposition chamber, comprising:
a chamber body having an interior volume contained between interior surfaces of the chamber body, interior surfaces of a gas distribution showerhead, and interior surfaces of a dome structure;
a substrate support structure disposed in the interior volume in an opposing relationship to the gas distribution showerhead; and
one or more lamp assemblies directing light through the dome structure, wherein the gas distribution showerhead comprises:
a body;
a plurality of conduits disposed in the body, each of the plurality of conduits having an opening extending to the interior surface of the body to deliver one or more gases to the interior volume; and
a coating disposed on the interior surfaces of the gas distribution showerhead.

9. The chamber of claim 8, wherein the interior surfaces of the chamber body comprise a ceramic coating.

10. The chamber of claim 8, wherein the coating has a coefficient of emissivity of at least about 0.8.

11. The chamber of claim 8, wherein the coating has an average surface roughness of about 180 micro-inches to about 220 micro-inches.

12. The chamber of claim 8, wherein the coating comprises a ceramic material.

13. The chamber of claim 8, wherein the body comprises a metallic material having an average surface roughness of about 80 micro inches to about 120 micro inches.

14. The chamber of claim 13, wherein the metallic material comprises stainless steel.

15. The chamber of claim 7, wherein the coating includes a thickness of about 50 microns to about 200 microns.

16. A method for processing a substrate, comprising:
transferring a first batch of one or more substrates on a substrate carrier plate to a processing volume of a chamber;
delivering one or more gases to the processing volume through a gas distribution plate having a coating on a surface facing the processing volume;
delivering thermal energy to the processing volume at an input energy to heat the first batch of one or more substrates to a set-point temperature and perform a first deposition process on the one or more substrates;
transferring the one or more substrates out of the processing volume;
transferring a second batch of one or more substrates to the processing volume of the chamber; and
heating the second batch of one or more substrates to the set-point temperature to perform a second deposition process on the one or more substrates, wherein the set-point temperature is maintained by varying the input energy by less than about 0.12%.

17. The method of claim 16, wherein the set-point temperature is about 900° C. to about 1,050° C.

18. The method of claim 16, wherein the input energy is provided by a plurality of lamps.

19. The method of claim 18, wherein the input energy is about 0.45 W/mm² to about 0.9 W/mm².

20. The method of claim 19, wherein the substrate carrier plate comprises a surface area of about 95,000 mm² to about 103,000 mm².

21. The method of claim 19, wherein the coating has a coefficient of emissivity of at least about 0.8.

22. The chamber of claim 19, wherein the coating has an average surface roughness of about 180 micro-inches to about 220 micro-inches.
